(19) United States
(12) Patent Application Publication
(10) Pub. No.: US 2026/0180525 A1
(43) Pub. Date: Jun. 25, 2026

(54) DIGITAL POWER AMPLIFIER WITH SCALED DRIVING STAGES

(71) Applicant: Intel Corporation, Santa Clara, CA (US)

(72) Inventors: Yuri ROZENFELD, Haifa (IL); Ofir DEGANI, Haifa (IL); Assaf BEN-BASSAT, Haifa (IL); Yishai EILAT, Alonei Aba (IL); Naor SHAY, Rehovot (IL)

(21) Appl. No.: 18/986,795

(22) Filed: Dec. 19, 2024

(51) Int. Cl. H03F 3/24

(52) U.S. Cl. CPC H03F 3/245; H03F 2200/451

(57) ABSTRACT

A digital polar amplifier includes an amplitude control portion, comprising a plurality of amplitude driver cells, the plurality of amplitude driver cells comprising a first subset of amplitude driver cells and a second subset of amplitude driver cells; wherein the amplitude control portion is configured to: receive an input signal; selectively activate one or more amplitude driver cells from the first subset and/or the second subset based on an amplitude control code; and control each of the selectively activated one or more amplitude driver cells to output an amplitude output signal corresponding to the input signal; and wherein each amplitude driver cell in the first subset is configured to generate a respective amplitude output signal at a first power level, and wherein each amplitude driver cell in the second subset is configured to generate a respective amplitude output signal at a second power level, lower than the first power level.

### BACKGROUND

Polar digital amplifiers utilize polar modulation techniques to amplify radio frequency signals. Unlike amplifiers that use Cartesian coordinates (e.g., using I-Q modulation), polar amplifiers represent signals in terms of their amplitude and phase, which are recombined at an output stage. In essence, the amplitude component is used to modulate the power supply voltage, while the phase component is applied to the radio frequency input of the power amplifier. Polar amplifiers may exhibit high efficiency and may be capable of operating with reduced power consumption, as compared to other amplification methods.

Polar digital amplifiers receive digital codes that correspond to the desired amplitude modulation and the desired phase modulation. Based on these codes, one or more of a plurality of amplifier cells in an amplifier cell array will be activated. Each amplifier cell includes one or more capacitors. Since the plurality of amplifier cells are connected to an output stage in parallel, the total capacitance remains stable, regardless of the number of activated amplifier cells. Accordingly, the activated amplifier cells (however many or few there are) must charge the entire plurality of capacitors (e.g. each capacitor within the plurality of amplifier cells). That is, the total driven capacitance of the amplifier cell array is static, and these capacitors must be charged by whatever cells of the amplifier cell array are activated based on the given code. When the relevant code requires that most or all of the plurality of amplifier cells are activated, this normally is of little consequence. When the relevant code requires that few of the plurality of amplifier cells are activated, however, this requires that the drivers from a small number of amplifier cells charge the capacitors of the entire amplifier cell array, which can result in undesirable delay/phase shift. To prevent the charging times from exceeding applicable allowances, a conventional solution for this problem is to increase the current output of each of the drivers of the amplifier cells. This creates additional expense, additional power requirements, and increases the relevant form factor, each of which may be undesirable in certain implementations. Other solutions have included the employment of specific resilient complementary metal oxide semiconductor process/nodes for the driving stages, which may significantly increase the production cost.

### BRIEF DESCRIPTION OF THE DRAWINGS

In the drawings, like reference characters generally refer to the same parts throughout the different views. The drawings are not necessarily to scale, emphasis instead generally being placed upon illustrating the exemplary principles of the embodiments. In the following description, various exemplary embodiments are described with reference to the following drawings, in which:

FIG. 1 depicts a non-monotonic amplitude integrated non-linearity;

FIG. 2 depicts a typology of a polar digital amplifier;

FIG. 3 depicts a conventional implementation with a uniform switch capacitor digital power amplifier driver cell array;

FIG. 4 depicts a non-uniform switch capacitor digital power amplifier array;

FIG. 5 depicts a unity capacitor transition time based on driver size;

FIG. 6 depicts an amplitude modulation phase modulation analysis for an amplifier having non-uniform arrays versus an amplifier having uniform arrays;

FIG. 7 is an amplitude modulation to amplitude modulation graph

FIG. 8 depicts current consumption versus power output of a device with uniform power arrays compared to a device with non-linear power arrays;

FIG. 9 depicts a chart that includes various measurements comparing the device with uniform-powered driver cells with the device having non-linear-powered driver cells; and

FIG. 10 depicts a digital polar amplifier.

### DESCRIPTION

The following detailed description refers to the accompanying drawings that show, by way of illustration, exemplary details and embodiments in which aspects of the embodiments may be practiced.

The word “exemplary” is used herein to mean “serving as an example, instance, or illustration”. Any embodiment or design described herein as “exemplary” is not necessarily to be construed as preferred or advantageous over other embodiments or designs.

Throughout the drawings, it should be noted that like reference numbers are used to depict the same or similar elements, features, and structures, unless otherwise noted.

The phrase “at least one” and “one or more” may be understood to include a numerical quantity greater than or equal to one (e.g., one, two, three, four, [ . . . ], etc.). The phrase “at least one of” with regard to a group of elements may be used herein to mean at least one element from the group consisting of the elements. For example, the phrase “at least one of” with regard to a group of elements may be used herein to mean a selection of: one of the listed elements, a plurality of one of the listed elements, a plurality of individual listed elements, or a plurality of a multiple of individual listed elements.

The words “plural” and “multiple” in the description and in the claims expressly refer to a quantity greater than one. Accordingly, any phrases explicitly invoking the aforementioned words (e.g., “plural [elements]”, “multiple [elements]”) referring to a quantity of elements expressly refers to more than one of the said elements. For instance, the phrase “a plurality” may be understood to include a numerical quantity greater than or equal to two (e.g., two, three, four, five, [ . . . ], etc.).

The phrases “group (of)”, “set (of)”, “collection (of)”, “series (of)”, “sequence (of)”, “grouping (of)”, etc., in the description and in the claims, if any, refer to a quantity equal to or greater than one, i.e., one or more. The terms “proper subset”, “reduced subset”, and “lesser subset” refer to a subset of a set that is not equal to the set, illustratively, referring to a subset of a set that contains less elements than the set.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and represent any information as understood in the art.

The terms “processor” or “controller” as, for example, used herein may be understood as any kind of technological entity that allows handling of data. The data may be handled according to one or more specific functions executed by the processor or controller. Further, a processor or controller as used herein may be understood as any kind of circuit, e.g., any kind of analog or digital circuit. A processor or a controller may thus be or include an analog circuit, digital circuit, mixed-signal circuit, logic circuit, processor, microprocessor, central processing unit (CPU), graphics processing unit (GPU), digital signal processor (DSP), field programmable gate array (FPGA), integrated circuit, application specific integrated circuit (ASIC), etc., or any combination thereof. Any other kind of implementation of the respective functions, which will be described below in further detail, may also be understood as a processor, controller, or logic circuit. It is understood that any two (or more) of the processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

In the following, a polar digital amplifier is disclosed in which the area occupied by the amplifier is divided non-uniformly such that the amplifier's driving stages that operate at low code (e.g., that are in use during low power operation) are sized significantly larger than the driving stages that operate at high code (high power). Otherwise stated, the driving stages that are operable with codes corresponding to low power output are sized such that they output more current than driving stages that are only operable with codes corresponding to high power output. This non-uniform configuration of driver output current results in improved dynamic performance while maintaining reduced power consumption compared to the conventional solution. It is expressly noted that, in the configuration disclosed herein, only the output stages corresponding to low code cells are increased (e.g., only these cells include drivers with increased current output as compared to that of the high code cells), thereby reducing the chip area as compared to conventional solutions, which corresponds therefore with decreased overall cost.

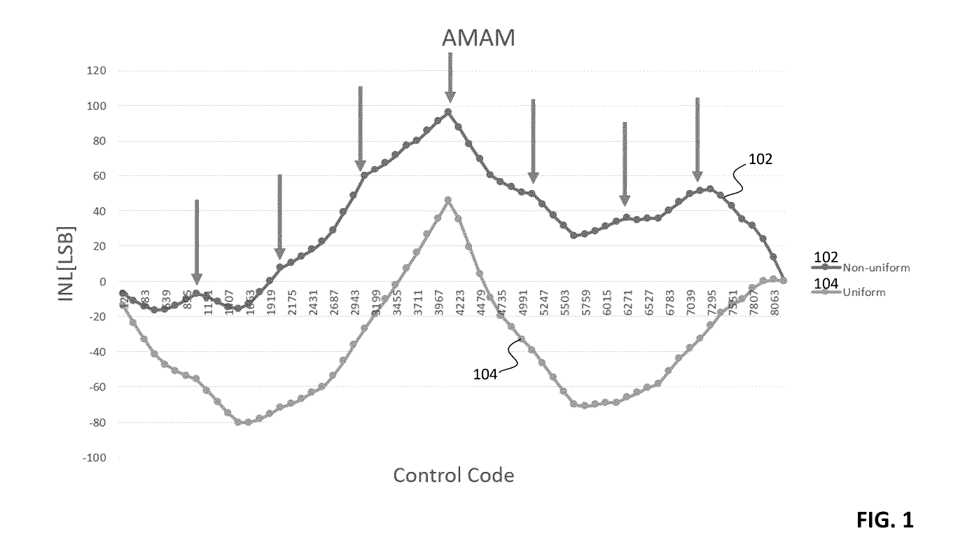

For context, FIG. 1 depicts a non-monotonic non-linear amplitude, integrated non-linearity that can be observed in the transition from smaller cells to larger cells within the non-uniform array. Specifically, in this figure, the non-uniform array 102 as disclosed herein, and a uniform array 104, for comparison purposes, are depicted in the context of an amplitude modulation to amplitude modulation graph. The integral non-linearity (INL) on the Y-axis indicates a measurement of deviation of an actual transfer function of the digital-to-analog converter (e.g. corresponding to the digital power amplifier) from an ideal straight line. The non-uniform array 102 depicts small peaks, which are marked by downward arrows, which indicate transition points between cell arrays of different driver sizes (e.g. between groups of drivers having different current outputs). In this example, which is offered for demonstrative purposes, and according to one exemplary configuration, each group of a particular driver size corresponds to 1024 bits of digital code, although this is merely provided as an example, and other links of digital code per driver size may be implemented.

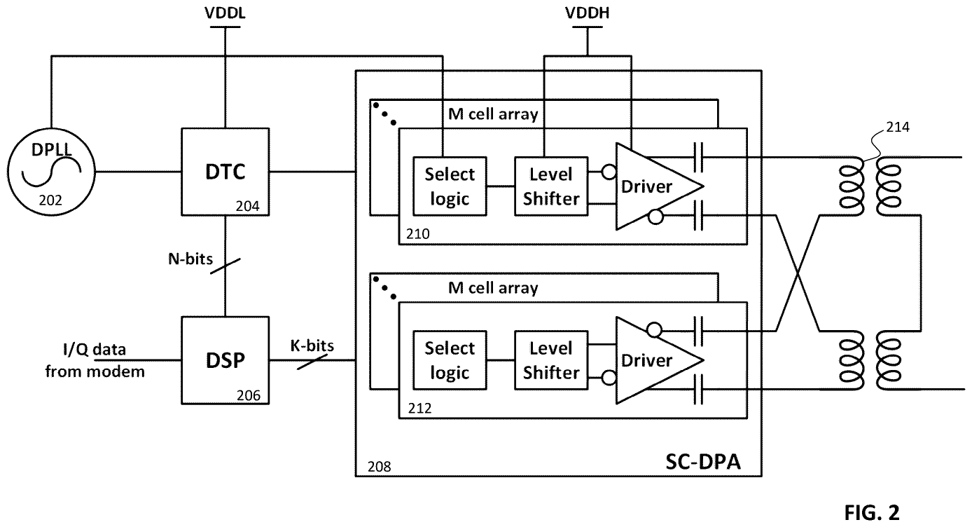

FIG. 2 depicts a typology of the polar digital amplifier as disclosed herein, according to an embodiment. This polar digital amplifier may be understood as a digital transmitter, since it may propagate its output into free space. The digital transmitter is based on a radiofrequency digital to analog converter at its output, meaning that it does not generate an analog version of a baseband signal and modulate this generated baseband signal for free space propagation, but rather generates a modulated signal from digital code.

The polar digital amplifier may include a digital phase locked loop 202, which may be a digital implementation of a phase locked loop, which may be capable of synchronizing a phase of an output signal with a reference signal. The digital phase locked loop 202 may stabilize and control a phase of the input signal, thereby ensuring proper synchronization for modulation. The polar digital amplifier may further include a digital to time converter 204, which may be configured to receive digital code, as well as an input signal from the digital phase locked loop 202. The polar digital amplifier may further include a digital signal processor 206, which may be configured to decompose an input signal into amplitude and phase components. The polar digital amplifier may be or include a switch capacitor digital power amplifier 208 which may itself include a first plurality of driver cell arrays 210 and a second plurality of driver cell arrays 212. Each of the driver cell arrays of the plurality of driver cell arrays (whether the first plurality or the second plurality) may include a select logic, a level shifter, and a driver. The switch capacitor digital polar amplifier 208 may be configured to receive a plurality of “K-bits” and a plurality of “N-bits”, wherein the K-bits represent digital code corresponding to phase shift (e.g., phase modulation) and the N-bits represent digital code corresponding to amplitude (e.g., amplitude modulation). In this configuration, the first driver cell array 210 may generate a signal having a modulated amplitude, and the second driver cell array 212 may generate a signal having a modulated phase. The amplitude modulated signal and the phase modulated signal are combined in an output stage 214. The magnitude of the amplitude modulated signal and the magnitude of the phase modulated signal depend on digital input codes, which control a number of driver cells in the respective driver cell array that are activated (e.g. turned on for a particular modulation). The number of driver cells in a given driver cell array may correspond to a desired range of power output, such that amplifiers requiring a limited range of power output may have a smaller number of driver cells in a driver cell array and amplifiers requiring a larger range of power output. Although a wide variety of quantities of driver cells is conceivable, it is noted for demonstrative purposes that the amplifier depicted in FIG. 1 may include sixty-four driver cells per driver cell array, although fewer or more are possible.

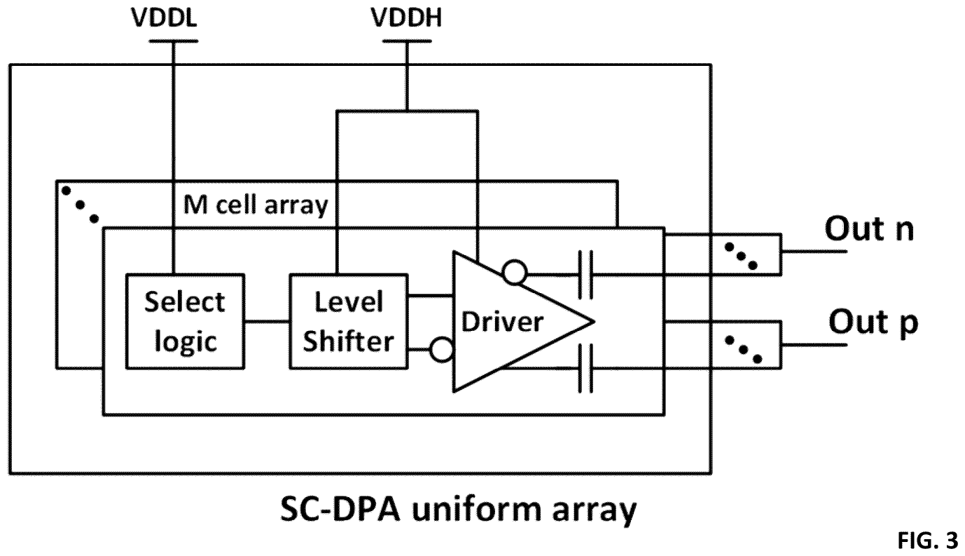

FIG. 3 depicts a conventional implementation of a power amplifier with a uniform switch capacitor digital power amplifier driver cell array. In this configuration, the driver cell array includes a plurality of driver cells, and each driver cell of the plurality of driver cells is configured to output with a predefined current. In this manner, the maximum power output of each driver cell of the plurality of driver cells within the uniform driver cell array is equal. As described above, this results in a problem when few driver cells of the driver cell array are activated. This problem arises out of the fact that the total capacitance of the driver cell array is constant, and that the active driver cells must charge this total capacitance of the driver cell array. In circumstances in which only few driver cells are active, the small number of driver cells must charge the total capacitance, which may result in slower charging times, unless additional measures are taken. A conventional solution to this problem is to increase the overall current output of each driver cell of the driver cell array, thereby allowing for rapid capacitor charging, even when only a small number of driver cells are activated. As stated above, however, this results in certain disadvantages which may be overcome as described herein.

In a polar, digital amplifier, a plurality of driver cells is available for amplification, and one or more driver cells of the plurality of driver cells are selectively activated (e.g., turned on) for amplification based on a digital code. The control of the output amplitude (e.g., the power) is achieved by controlling the number of these driver cells that are turned on. In the conventional design, equally weighted cells are placed in the array, and changes between binary and thermometric cells are achieved only by employing different capacitor sizing. That is, each cell output stage is conventionally sized the same (e.g. the drivers output the same current), so the “driving strength” is equal for all cells.

However, as cells are turned off, fewer drivers are employed in the power driving to the load and have to drive the off-state capacitors (a.k.a. off state cells). This results in more delay (a.k.a. phase) to the output signal since the fewer number of equally-weighted cells take longer to charge the system's capacitors. Conventionally, this problem has been mitigated by increasing the strength of all the cells'driving stages, resulting in increased current consumption and area. That is, each cell is sized to have a larger current output so that an acceptable charging speed can be achieved when only a small number of cells are activated.

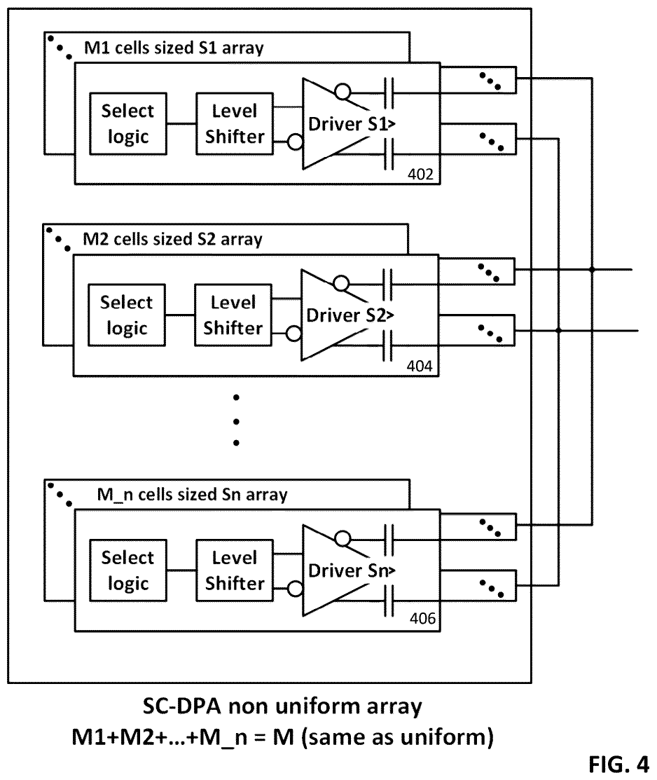

FIG. 4 depicts a non-uniform switch capacitor digital power amplifier array. In this figure, each of the first driver cell array and the second driver cell array include a plurality of driver cell groups. Illustratively, the first driver cell array is depicted as 402, the second driver cell array is depicted as 404, and an nth driver cell array is depicted as 406 (any number of arrays may be presence between the second driver cells array 404 and the nth driver cell array 406). In this manner, the polar, digital power amplifier may be configured such that, for amplification codes corresponding to low power, only one or more cells of the first driver cell array 402 will be activated; for larger power outputs, one or more cells of the second driver cell array 404 will be activated in addition to one or more cells (or potentially all cells) of the first driver cell array 402; and for the greatest power outputs, one or more cells of the nth driver cells array 406 will be activated, in additional to one or more (or potentially all) cells of the first driver cell array 402 and one or more (or potentially all) cells of the second driver array 404 (and one or more cells of any other driver cell arrays between the second driver cell array 404 and the nth driver cell array 406). Notably, the cells of the first driver cell array 402 may be configured to have the greatest current output; the cells of the second driver cells array 404 may be configured to have less current output than the cells of the first driver cell array 402; and the cells of the nth driver cell array 406 may be configured to have less current output than the cells of the second driver cell array 404 or any driver cell arrays between the second driver cell array 404 and the nth driver cell array 406. In this manner, codes corresponding to lower power may be driven by cells with the greatest current output, so that the device's total capacitance can be charged within an acceptable duration, and codes corresponding to greater power can be powered by additional driver cells (e.g., of one or more additional driver cell arrays) whose driver cells output less current than the lower order driver cell arrays. Accordingly, smaller (e.g., smaller current) driver cells can be utilized for larger power amplification, since a greater number of cells are available to charge the total capacitance, and larger driver cells can be relied upon for smaller power amplification, since fewer cells will be available to charge the total capacitance. This results in improved unity cap transition time when total driver size is increased.

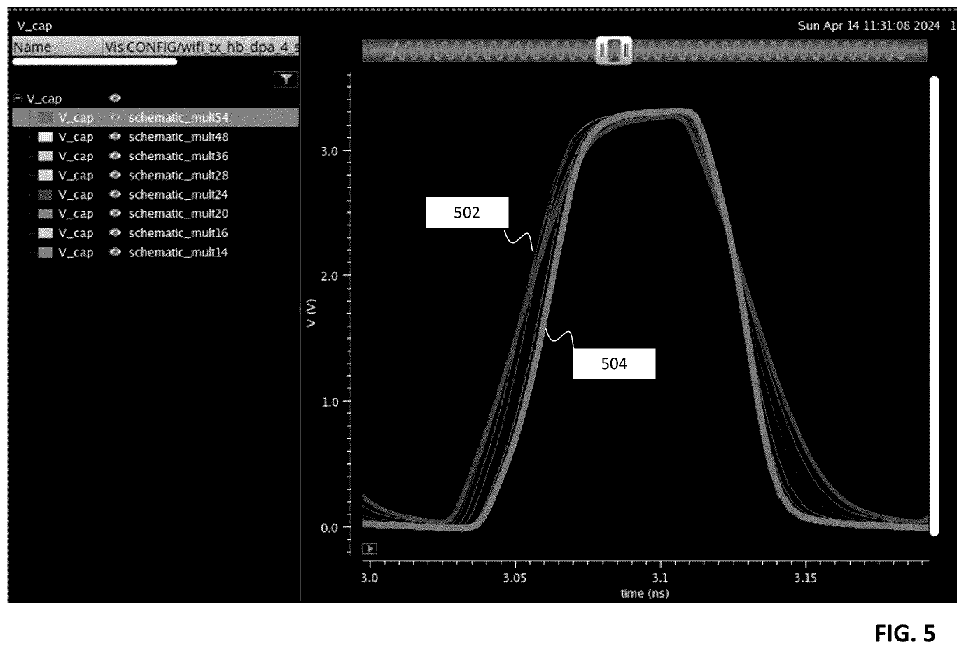

FIG. 5 depicts a unity capacitor transition time based on driver size. As can be seen, the larger the driver's output power, the more rapidly the unity capacitor charges. For example, a first driver 502, having a lower driver output power, results in a more gradual (e.g., longer, less steep) charging period than the second driver 504, having a larger power output.

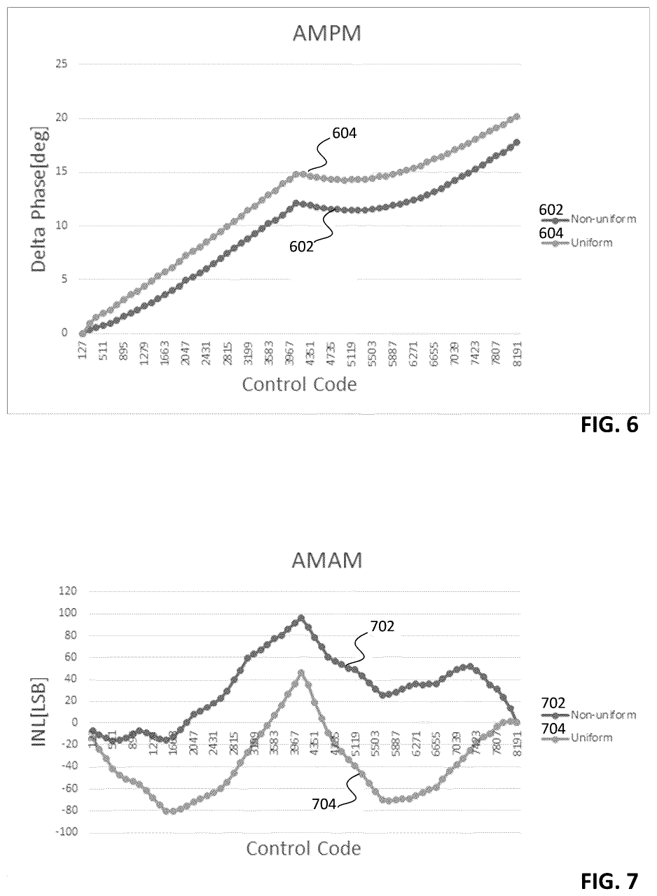

FIG. 6 depicts an amplitude modulation phase modulation (AMPM) analysis for an amplifier having non-uniform arrays 602 versus an amplifier having uniform arrays 604, which, in essence, depicts a change in phase based on control code for the linear arrays 604 and the non-linear arrays 602 of driver cells. As can be seen, the device having uniform arrays 604 consistently exhibits a greater phase shift than the device having non-linear arrays.

FIG. 7 is an Amplitude Modulation to Amplitude Modulation graph, which tracks how an input amplitude modulation (e.g., control codes) is translated to the output amplitude modulation. In particular, this depicts a measure of deviation of an actual amplitude output from an ideal output. As can be seen, the device having drivers arrays of non-uniform output powers 702 exhibits less peak to peak deviation from an ideal output, as compared to the device having uniform output powers 704. For example, the integral non-linearity from codes 0 to approximately 2000 is between 0 and −20 for the non-uniform output powers 702 and between 0 and approximately −85 for the uniform output powers 704.

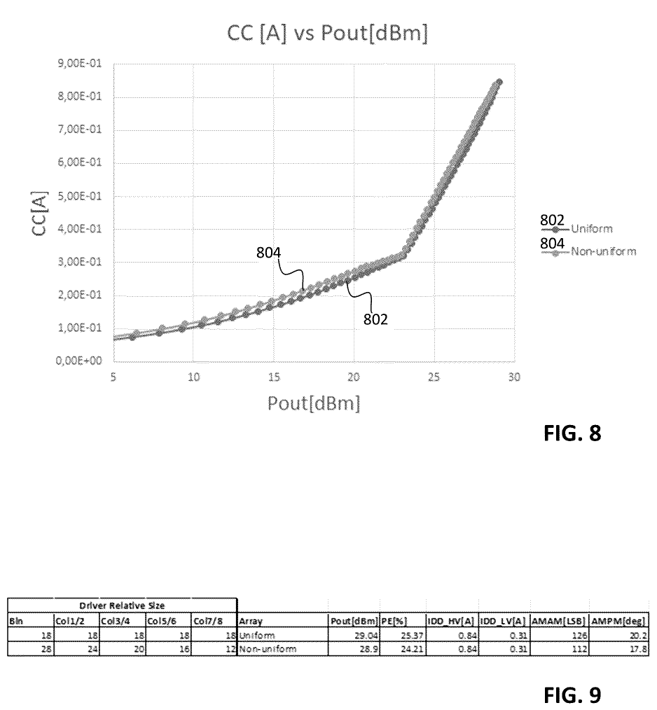

FIG. 8 depicts the current consumption versus power output of a device with uniform (e.g. linear) power arrays 802 and the device with non-linear 804 power arrays. As can be seen, the current consumption of each device is quite similar. The device having non-uniform power driver arrays 804 appears to output slightly more current than the device with uniform power driver arrays 802, which is generally to be expected, given that the arrays for the lowest codes would be sized to have greater current output than devices for higher codes. Nevertheless, the output currents are comparable.

FIG. 9 is a chart that includes various measurements comparing the device with uniform-powered driver cells with the device having non-linear-powered driver cells. In this exemplary confirmation, each cluster of driver cells in the uniform driver cell device has a power that is indicated by 18. In contrast, the powers of the non-uniform driver cell clusters range from 28 (e.g., corresponding to the lowest codes) to 12 (corresponding to the highest codes). The device with the uniform driver cell arrays exhibited an average output power of 29.04 dBm, compared to the device with the non-uniform drive cell arrays, which exhibited an output power of 28.9 dBm. The device with the uniform driver cell arrays exhibited a power efficiency of 25.37%, compared to the device with the non-uniform drive cell arrays, which exhibits a power efficiency of 24.21%. Both devices draw the same amount of current, whether at high voltage supply [IDD_HV] or low voltage supply [IDD_LV]. The device with the uniform driver cells arrays exhibited slightly more amplitude modulation-to-amplitude modulation distortion at 126, compared to the device with non-uniform driver cell arrays, which exhibited amplitude modulation-to-amplitude modulation of 112. Finally, the device with the uniform driver cells arrays exhibited slightly more amplitude modulation-to-phase modulation distortion at 20.2 degrees, compared to the device with non-uniform driver cell arrays, which exhibited amplitude modulation-to-phase modulation of 17.8 degrees.

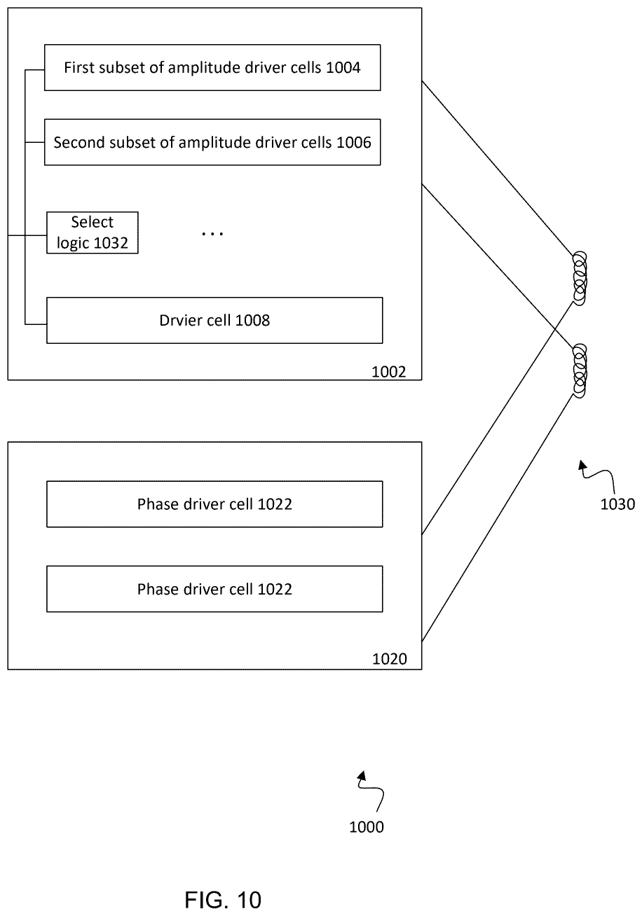

FIG. 10 depicts a digital polar amplifier 1000, including an amplitude control portion 1002, including a plurality of amplitude driver cells 1004 and 1006, the plurality of amplitude driver cells 1004, and 1006 including a first subset of amplitude driver cells 1004 and a second subset of amplitude driver cells 1006. The amplitude control portion 1002 may be configured to receive an input signal; selectively activate one or more amplitude driver cells from the first subset 1004 and/or the second subset 1006 based on an amplitude control code; and control each of the selectively activated one or more amplitude driver cells to output an amplitude output signal corresponding to the input signal. Each amplitude driver cell in the first subset 1004 is configured to generate a respective amplitude output signal at a first power level, and each amplitude driver cell in the second subset 1006 is configured to generate a respective amplitude output signal at a second power level, lower than the first power level.

The digital polar amplifier may include a phase control portion 1020, which may include a plurality of phase driver cells 1022. The phase control portion 1020 may be configured to receive the input signal; generate a phase modified signal by changing a phase of the input signal by selectively activating one or more phase driver cells of the plurality of phase driver cells 1022 based on a phase control code; and output the phase modified signal. The digital polar amplifier may also include a power combiner 1030, which may be configured to combine an output of the amplitude control portion and an output of the phase control portion.

The amplitude control portion may be configured to operate the first subset 1004 for a first control code corresponding to a first amplitude and to operate the first subset 1004 and the second subset 1006 for a second control code corresponding to a second amplitude, greater than the first amplitude. Each amplitude driver cell of the plurality of amplitude driver cells may include a select logic 1032, which may be configured to activate or deactivate a respective amplitude driver cell based on the amplitude control code.

Each amplitude driver cell of the plurality of amplitude driver cells may include a level shifter, which may be configured to receive a carrier signal and to output the carrier signal at an increased power level. The amplitude output signal corresponding to the input signal may include a portion of the input signal whose power has been increased by the level shifter. Furthermore, each amplitude driver cell of the plurality of amplitude driver cells may include a driver, which may be configured to receive the carrier signal at the increased power level as an input signal and to output the input signal at a predetermined power. Each of the plurality of amplitude driver cells may include a capacitor, and an output of each amplitude driver cell of the plurality of amplitude driver cells may be connected to a capacitor of all other amplitude driver cells in parallel. In this manner, the amplitude control portion may be configured to output a differential amplitude control portion signal at a positive differential amplitude control portion signal terminal and a negative differential amplitude control portion signal terminal. The phase control portion may be configured to output a differential phase control portion signal at a positive differential phase control portion signal terminal and a negative differential phase control portion signal terminal. The positive differential amplitude control portion signal terminal may be connected to the negative differential phase control portion signal terminal; and the negative differential amplitude control portion signal terminal is connected to the positive differential phase control portion signal terminal.

Further embodiments will be disclosed by way of Example:

In Example 1, a digital polar amplifier, including an amplitude control portion, including a plurality of amplitude driver cells, the plurality of amplitude driver cells including a first subset of amplitude driver cells and a second subset of amplitude driver cells; wherein the amplitude control portion is configured to: receive an input signal; selectively activate one or more amplitude driver cells from the first subset and/or the second subset based on an amplitude control code; and control each of the selectively activated one or more amplitude driver cells to output an amplitude output signal corresponding to the input signal; and wherein each amplitude driver cell in the first subset is configured to generate a respective amplitude output signal at a first power level, and wherein each amplitude driver cell in the second subset is configured to generate a respective amplitude output signal at a second power level, lower than the first power level.

In Example 2, the digital polar amplifier of Example 1, further including: a phase control portion, including a plurality of phase driver cells, wherein the phase control portion is configured to: receive the input signal; generate a phase modified signal by changing a phase of the input signal by selectively activating one or more phase driver cells of the plurality of phase driver cells based on a phase control code; and output the phase modified signal; and a power combiner, configured to combine an output of the amplitude control portion and an output of the phase control portion.

In Example 3, the digital polar amplifier of Example 1 or 2, wherein the amplitude control portion is configured to operate the first subset for a first control code corresponding to a first amplitude and to operate the first subset and the second subset for a second control code corresponding to a second amplitude, greater than the first amplitude.

In Example 4, the digital polar amplifier of any one of Examples 1 to 3, wherein each amplitude driver cell of the plurality of amplitude driver cells includes a select logic, configured to activate or deactivate a respective amplitude driver cell based on the amplitude control code.

In Example 5, the digital polar amplifier of any one of Examples 1 to 4, wherein each amplitude driver cell of the plurality of amplitude driver cells includes a level shifter, configured to receive a carrier signal and to output the carrier signal at an increased power level; and wherein the amplitude output signal corresponding to the input signal includes a portion of the input signal whose power has been increased by the level shifter.

In Example 6, the digital polar amplifier of Example 5, wherein each amplitude driver cell of the plurality of amplitude driver cells includes a driver, configured to receive the carrier signal at the increased power level as an input signal and to output the input signal at a predetermined power.

In Example 7, the digital polar amplifier of any one of Examples 1 to 6, wherein each of the plurality of amplitude driver cells includes a capacitor, and wherein an output of each amplitude driver cell of the plurality of amplitude driver cells is connected to a capacitor of all other amplitude driver cells in parallel.

In Example 8, the digital polar amplifier of any one of Examples 2 to 7, wherein the amplitude control portion is configured to output a differential amplitude control portion signal at a positive differential amplitude control portion signal terminal and a negative differential amplitude control portion signal terminal; wherein the phase control portion is configured to output a differential phase control portion signal at a positive differential phase control portion signal terminal and a negative differential phase control portion signal terminal; wherein the positive differential amplitude control portion signal terminal is connected to the negative differential phase control portion signal terminal; and wherein the negative differential amplitude control portion signal terminal is connected to the positive differential phase control portion signal terminal.

In Example 9, a digital polar amplifier, including: an amplitude controller, including a plurality of amplitude driver cells, the plurality of amplitude driver cells including a first subset of amplitude driver cells and a second subset of amplitude driver cells; wherein the amplitude controller is for: receiving an input signal; selectively activating one or more amplitude driver cells from the first subset and/or the second subset based on an amplitude control code; and controlling each of the selectively activated one or more amplitude driver cells to output an amplitude output signal corresponding to the input signal; and wherein each amplitude driver cell in the first subset is for generating a respective amplitude output signal at a first power level, and wherein each amplitude driver cell in the second subset is for generating a respective amplitude output signal at a second power level, lower than the first power level.

In Example 10, the digital polar amplifier of Example 9, further including: a phase controller, including a plurality of phase driver cells, wherein the phase controller is for: receiving the input signal; generating a phase modified signal by changing a phase of the input signal by selectively activating one or more phase driver cells of the plurality of phase driver cells based on a phase control code; and outputting the phase modified signal; and a power combiner, for combining an output of the amplitude controller and an output of the phase controller.

In Example 11, the digital polar amplifier of Example 9 or 10, wherein the amplitude controller is for operating the first subset for a first control code corresponding to a first amplitude and for operating the first subset and the second subset for a second control code corresponding to a second amplitude, greater than the first amplitude.

In Example 12, the digital polar amplifier of any one of Examples 9 to 11, wherein each amplitude driver cell of the plurality of amplitude driver cells includes a select logic for activating or deactivating a respective amplitude driver cell based on the amplitude control code.

In Example 13, the digital polar amplifier of any one of Examples 9 to 12, wherein each amplitude driver cell of the plurality of amplitude driver cells includes a level shifter for receiving a carrier signal and outputting the carrier signal at an increased power level; and wherein the amplitude output signal corresponding to the input signal includes a portion of the input signal whose power has been increased by the level shifter.

In Example 14, the digital polar amplifier of Example 13, wherein each amplitude driver cell of the plurality of amplitude driver cells includes a driver for receiving the carrier signal at the increased power level as an input signal and for outputting the input signal at a predetermined power.

In Example 15, the digital polar amplifier of any one of Examples 9 to 14, wherein each of the plurality of amplitude driver cells includes a capacitor, and wherein an output of each amplitude driver cell of the plurality of amplitude driver cells is connected to a capacitor of all other amplitude driver cells in parallel.

In Example 16, the digital polar amplifier of any one of Examples 10 to 15, wherein the amplitude control portion is for outputting a differential amplitude control portion signal at a positive differential amplitude control portion signal terminal and a negative differential amplitude control portion signal terminal; wherein the phase control portion is configured to output a differential phase control portion signal at a positive differential phase control portion signal terminal and a negative differential phase control portion signal terminal; wherein the positive differential amplitude control portion signal terminal is connected to the negative differential phase control portion signal terminal; and wherein the negative differential amplitude control portion signal terminal is connected to the positive differential phase control portion signal terminal.

In Example 17, a method of digital polar amplification, including: receiving an input signal in an amplitude control portion; selectively activating one or more amplitude driver cells from a first subset of amplitude driver cells in the amplitude control portion and/or selectively activating one or more amplitude driver cells from a second subset of amplitude driver cells of the amplitude control portion based on an amplitude control code; and controlling each of the selectively activated one or more amplitude driver cells to output an amplitude output signal corresponding to the input signal; and wherein each amplitude driver cell in the first subset is configured to generate a respective amplitude output signal at a first power level, and wherein each amplitude driver cell in the second subset is configured to generate a respective amplitude output signal at a second power level, lower than the first power level.

In Example 18, the method of digital polar amplification of Example 17, further including: receiving the input signal at a phase control portion including a plurality of phase driver cells, wherein the phase control portion is configured to generate a phase modified signal by changing a phase of the input signal by selectively activating one or more phase driver cells of the plurality of phase driver cells based on a phase control code; outputting the phase modified signal; and combining an output of the amplitude control portion and an output of the phase control portion.

In Example 19, the method of digital polar amplification of Example 17 or 18, further including operating the first subset for a first control code corresponding to a first amplitude and operating the first subset and the second subset for a second control code corresponding to a second amplitude, greater than the first amplitude.

In Example 20, the method of digital polar amplification of any one of Examples 17 to 19, wherein each amplitude driver cell of the plurality of amplitude driver cells includes a select logic; further including activating or deactivating, using the logic, a respective amplitude driver cell based on the amplitude control code.

In Example 21, the method of digital polar amplification of any one of Examples 17 to 20, wherein each amplitude driver cell of the plurality of amplitude driver cells includes a level shifter; further including receiving a carrier signal at the level shifter and outputting from the level shifter the carrier signal at an increased power level; and wherein the amplitude output signal corresponding to the input signal includes a portion of the input signal whose power has been increased by the level shifter.

In Example 22, the method of digital polar amplification of Example 21, wherein each amplitude driver cell of the plurality of amplitude driver cells includes a driver; further including receiving the carrier signal at the increased power level as an input signal and to output the input signal at a predetermined power.

In Example 23, the method of digital polar amplification of any one of Examples 17 to 22, wherein each of the plurality of amplitude driver cells includes a capacitor, and wherein an output of each amplitude driver cell of the plurality of amplitude driver cells is connected to a capacitor of all other amplitude driver cells in parallel.

In Example 24, the method of digital polar amplification of any one of Examples 18 to 23, further including: outputting from the amplitude control portion a differential amplitude control portion signal; outputting from the phase control portion a differential phase control portion signal; combining a positive differential amplitude control portion signal with a negative differential phase control portion signal; and combining a negative differential amplitude control portion signal with a positive differential phase control portion signal.

While the above descriptions and connected figures may depict components as separate elements, skilled persons will appreciate the various possibilities to combine or integrate discrete elements into a single element. Such may include combining two or more circuits for form a single circuit, mounting two or more circuits onto a common chip or chassis to form an integrated element, executing discrete software components on a common processor core, etc. Conversely, skilled persons will recognize the possibility to separate a single element into two or more discrete elements, such as splitting a single circuit into two or more separate circuits, separating a chip or chassis into discrete elements originally provided thereon, separating a software component into two or more sections and executing each on a separate processor core, etc.

It is appreciated that implementations of methods detailed herein are demonstrative in nature, and are thus understood as capable of being implemented in a corresponding device. Likewise, it is appreciated that implementations of devices detailed herein are understood as capable of being implemented as a corresponding method. It is thus understood that a device corresponding to a method detailed herein may include one or more components configured to perform each aspect of the related method.

All acronyms defined in the above description additionally hold in all claims included herein.

What is claimed is:

1. An apparatus, comprising:
an amplitude control portion, comprising a plurality of amplitude driver cells, the plurality of amplitude driver cells comprising a first subset of amplitude driver cells and a second subset of amplitude driver cells;
wherein the amplitude control portion is configured to:
receive an input signal;
selectively activate one or more amplitude driver cells from the first subset and/or the second subset based on an amplitude control code; and
control the selectively activated one or more amplitude driver cells to output an amplitude output signal corresponding to the input signal; and
wherein amplitude driver cell in the first subset is configured to generate a respective amplitude output signal at a first power level, and wherein amplitude driver cell in the second subset is configured to generate a respective amplitude output signal at a second power level, lower than the first power level.

2. The apparatus of claim 1, further comprising:
a phase control portion, comprising a plurality of phase driver cells, wherein the phase control portion is configured to:
receive the input signal;
generate a phase modified signal by changing a phase of the input signal by selectively activating one or more phase driver cells of the plurality of phase driver cells based on a phase control code; and
output the phase modified signal; and
a power combiner, configured to combine an output of the amplitude control portion and an output of the phase control portion.

3. The apparatus of claim 1, wherein the amplitude control portion is configured to operate the first subset for a first control code corresponding to a first amplitude and to operate the first subset and the second subset for a second control code corresponding to a second amplitude, greater than the first amplitude.

4. The apparatus of claim 1, wherein the amplitude driver cell comprises a select logic, configured to activate or deactivate a respective amplitude driver cell based on the amplitude control code.

5. The apparatus of claim 1, wherein the amplitude driver cell comprises a level shifter, configured to receive a carrier signal and to output the carrier signal at an increased power level; and wherein the amplitude output signal corresponding to the input signal comprises a portion of the input signal whose power has been increased by the level shifter.

6. The apparatus of claim 25, wherein the amplitude driver cell of the plurality of amplitude driver cells comprises a driver, configured to receive the carrier signal at the increased power level as an input signal and to output the input signal at a predetermined power.

7. The apparatus of claim 1, wherein the amplitude driver cells comprises a capacitor, and wherein an output of the amplitude driver cell is coupled to a capacitor of the amplitude driver cells in parallel.

8. The apparatus of claim 2, wherein the amplitude control portion is configured to output a differential amplitude control portion signal at a positive differential amplitude control portion signal terminal and a negative differential amplitude control portion signal terminal; wherein the phase control portion is configured to output a differential phase control portion signal at a positive differential phase control portion signal terminal and a negative differential phase control portion signal terminal; wherein the positive differential amplitude control portion signal terminal is coupled to the negative differential phase control portion signal terminal; and wherein the negative differential amplitude control portion signal terminal is coupled to the positive differential phase control portion signal terminal.

9. The apparatus of claim 1, wherein the apparatus is provided in at least one of an integrated circuit, a System on Chip, a System in Package or a computing device.

10. A method, comprising:
receiving an input signal in an amplitude control portion;
selectively activating one or more amplitude driver cells from a first subset of amplitude driver cells in the amplitude control portion, and/or selectively activating one or more amplitude driver cells from a second subset of amplitude driver cells of the amplitude control portion based on an amplitude control code; and
controlling the selectively activated one or more amplitude driver cells to output an amplitude output signal corresponding to the input signal; and
wherein each amplitude driver cell in the first subset is configured to generate a respective amplitude output signal at a first power level, and wherein each amplitude driver cell in the second subset is configured to generate a respective amplitude output signal at a second power level, lower than the first power level.

11. The method of digital polar amplification of claim, further comprising:
receiving the input signal at a phase control portion comprising a plurality of phase driver cells, wherein the phase control portion is configured to generate a phase modified signal by changing a phase of the input signal by selectively activating one or more phase driver cells of the plurality of phase driver cells based on a phase control code;
outputting the phase modified signal; and
combining an output of the amplitude control portion and an output of the phase control portion.

12. The method of digital polar amplification of claim, further comprising operating the first subset for a first control code corresponding to a first amplitude and operating the first subset and the second subset for a second control code corresponding to a second amplitude, greater than the first amplitude.

13. The method of digital polar amplification of claim, wherein each amplitude driver cell of the first subset of amplitude driver cells comprises a select logic; and
further comprising activating or deactivating, using the select logic, a respective amplitude driver cell based on the amplitude control code.

14. The method of digital polar amplification of claim, wherein each amplitude driver cell of the first subset of amplitude driver cells comprises a level shifter; further comprising receiving a carrier signal at the level shifter and outputting from the level shifter the carrier signal at an increased power level; and
wherein the amplitude output signal corresponding to the input signal comprises a portion of the input signal whose power has been increased by the level shifter.

15. The method of digital polar amplification of claim 1114, wherein each amplitude driver cell of the first subset of amplitude driver cells comprises a driver; and
further comprising receiving the carrier signal at the increased power level as an input signal and to output the input signal at a predetermined power.

16. The method of digital polar amplification of claim, wherein each amplitude driver cell of the first subset of amplitude driver cells comprises a capacitor, and wherein an output of each amplitude driver cell of the first subset of amplitude driver cells is connected to a capacitor of other amplitude driver cells in parallel.

17. The method of digital polar amplification of claim 11, further comprising:
outputting from the amplitude control portion a differential amplitude control portion signal;
outputting from the phase control portion a differential phase control portion signal;
combining a positive differential amplitude control portion signal with a negative differential phase control portion signal; and
combining a negative differential amplitude control portion signal with a positive differential phase control portion signal.

18. A non-transitory computer readable medium, comprising instructions which, if executed by a processor, cause the processor to control an amplitude control portion of a digital polar amplifier to:
receive an input signal in an amplitude control portion;
selectively activate one or more amplitude driver cells from a first subset of amplitude driver cells in the amplitude control portion, and/or selectively activate one or more amplitude driver cells from a second subset of amplitude driver cells of the amplitude control portion based on an amplitude control code; and
control the selectively activated one or more amplitude driver cells to output an amplitude output signal corresponding to the input signal; and
wherein each amplitude driver cell in the first subset is configured to generate a respective amplitude output signal at a first power level, and wherein each
amplitude driver cell in the second subset is configured to generate a respective amplitude output signal at a second power level, lower than the first power level;
wherein the amplitude control portion comprises a plurality of amplitude driver cells, the plurality of amplitude driver cells comprising a first subset of amplitude driver cells and a second subset of amplitude driver cells.

19. The non-transitory computer readable medium of claim, wherein the instructions are further configured to cause the processor to control a phase control portion of the digital polar amplifier to:
receive the input signal;
generate a phase modified signal by changing a phase of the input signal by selectively activating one or more phase driver cells of the plurality of phase driver cells based on a phase control code; and
output the phase modified signal; and
wherein the phase control portion comprises a plurality of phase driver cells.

20. The non-transitory computer readable medium of claim, wherein the instructions are further configured to cause the processor operate the first subset for a first control code corresponding to a first amplitude and to operate the first subset and the second subset for a second control code corresponding to a second amplitude, greater than the first amplitude.
